(19) United States
(12) Patent Application Publication
(10) Pub. No.: US 2022/0390657 A1
(43) Pub. Date: Dec. 8, 2022

(54) DISPLAY DEVICE, ELECTRONIC APPARATUS, AND METHOD FOR MANUFACTURING THE DISPLAY DEVICE

(71) Applicant: Sony Semiconductor Solutions Corporation, Kanagawa (JP)

(72) Inventors: Masashi Nakata, Kanagawa (JP); Seiichiro Jinta, Kanagawa (JP)

(21) Appl. No.: 17/790,025

(22) PCT Filed: Feb. 4, 2021
(86) PCT No.: PCT/JP2021/004047

§ 371 Date: Jun. 29, 2022

(30) Foreign Application Priority Data
Feb. 13, 2020 (JP) 2020-022417

(51) Int. Cl. G02B 5/20; G02B 1/118

(52) U.S. Cl. CPC G02B 5/208; G02B 1/118; G06V 40/1318

(57) ABSTRACT

To improve transmittance without impairing display quality.

A display device includes: a substrate; a first display region disposed on the substrate, the first display region having a plurality of pixels; and a second display region disposed on the substrate, the second display region having a plurality of pixels, in which the substrate has a first transmittance in the first display region, and the substrate has a second transmittance in the second display region higher than the first transmittance.

### TECHNICAL FIELD

The present disclosure relates to a display device, an electronic apparatus, and a method for manufacturing the display device.

### BACKGROUND ART

In a recent electronic apparatus such as a smartphone, a mobile phone, or a personal computer (PC), the frame (bezel) of its display panel is equipped with various sensors such as a camera. However, there is a demand for making the outer size of such an electronic apparatus as compact as possible without affecting the screen size, and the bezel width tends to be narrowed. In view of such a background, a technique has been proposed in which a camera module is disposed immediately below the display panel and subject light passed through the display panel is shot by the camera module.

### CITATION LIST

### Patent Document

Patent Document 1: US Patent Publication No. 2018/0069060

### SUMMARY OF THE INVENTION

### Problems to be Solved by the Invention

A sealing material for preventing moisture or the like from intruding from the outside is required for a display panel, and polyimide is typically used for the sealing material. Polyimide is also excellent in heat resistance, and can withstand a heat treatment process in formation of a thin film transistor (TFT).

Polyimide, however, is low in transmittance to visible light. When shooting is performed with the camera module through the display panel as described above, the shooting image quality deteriorates.

Although development to make polyimide transparent has also been advanced, when polyimide is made transparent, heat resistance deteriorates typically. Thus, there is a possibility that the electrical characteristics of the TFT formed on the display panel are deteriorated.

Therefore, the present disclosure provides a display device, an electronic apparatus, and a method for manufacturing the display device that enable improvement in transmittance without impairing display quality.

### Solutions to Problems

In order to solve the above problems, according to the present disclosure, provided is a display device including: a substrate;

a first display region disposed on the substrate, the first display region having a plurality of pixels; and

a second display region disposed on the substrate, the second display region having a plurality of pixels,

in which the substrate has a first transmittance in the first display region, and

the substrate has a second transmittance in the second display region higher than the first transmittance.

The second display region may face a sensing device disposed on a side of a face opposite to a display face on the substrate.

The display device may further include: a first film disposed on the side of the face opposite to the display face within the first display region, the first film having the first transmittance.

The display device may further include: a second film disposed on the side of the face opposite to the display face within the second display region, the second film having the second transmittance.

The second film may be disposed on the side of the face opposite to the display face in at least part of the second display region, the part including a boundary portion between adjacent pixels within the second display region.

A ratio of an area of the second film to an area of a light emitting region within the second display region may be 30% or more.

The second film may have a function of cutting infrared light.

The second film may be disposed at an opening formed by removal of part of the first film, and

a transmittance of a boundary portion between the first film and the second film may vary continuously or stepwise from the first film to the second film.

The first film may contain polyimide, and

the second film may contain a material higher in transmittance than the polyimide of the first film.

The second film may have at least one of a concave portion or a convex portion.

The display device may further include: an optical lens including the second film.

The display device may further include: a moth-eye structure layer including the second film.

The first film may be provided in at least part of the second display region, the at least part excluding a boundary portion between adjacent pixels within the second display region, and

an opening of the first film may be provided at the boundary portion between the adjacent pixels within the second display region.

The first transmittance to visible light having a wavelength of 400 nm may be 0 to 50%, and

the second transmittance to the visible light may be 51 to 100%.

According to the present disclosure, provided is an electronic apparatus including: a display device;

a sensing device disposed opposite a display face of the display device,

in which the display device includes:

a substrate;

a first display region disposed on the substrate, the first display region having a plurality of pixels; and

a second display region disposed on the substrate, the second display region having a plurality of pixels,

the substrate has a first transmittance in the first display region, and

the substrate has a second transmittance in the second display region higher than the first transmittance.

The sensing device may include an imaging sensor.

The sensing device may include a biometric-information detection sensor.

A plurality of the second display regions may be provided on the display face, and

a plurality of the sensing devices may be disposed corresponding to the plurality of the second display regions.

The respective second transmittances of at least two of the plurality of the second display regions may be different from each other.

According to the present disclosure, provided is a method for manufacturing a display device, the method comprising:

forming a first film having a first transmittance on a first support substrate;

forming a light emitting layer on the first film;

forming a protective film on the light emitting layer;

forming a second support substrate on the protective film;

removing the first support substrate; and

forming an opening at the first film so as to be coincident with a disposition place of a sensing device.

The method may further include: forming a second film at the opening, the second film having a second transmittance higher than the first transmittance.

According to the present disclosure, provided is a manufacturing method, the method comprising:

forming a first film having a first transmittance on a support substrate;

forming an opening at the first film so as to be coincident with a disposition place of a sensing device;

filling the opening with an insulating member;

forming a first protective film on the first film;

forming a light emitting layer on the first protective film;

forming a second protective film on the light emitting layer; and

removing the insulating member to form the opening at the first film.

The method may further include: forming a second film at the opening formed by the removing, the second film being higher in transmittance than the first film.

### BRIEF DESCRIPTION OF DRAWINGS

FIG. 1 is a schematic external view of an electronic apparatus equipped with a display device according to a first embodiment.

FIG. 2A is a schematic sectional view illustrating part of a second display region.

FIG. 2B is a schematic sectional view illustrating part of a first display region.

FIG. 2C is a schematic sectional view of a display device including the first display region and the second display region.

FIG. 2D is a schematic sectional view of the display device with a first film and a second film disposed in the second display region.

FIG. 3A is a sectional view illustrating a manufacturing process of the display device according to the first embodiment.

FIG. 3B is a process sectional view following FIG. 3A.

FIG. 3C is a process sectional view following FIG. 3B.

FIG. 3D is a process sectional view following FIG. 3C.

FIG. 3E is a process sectional view following FIG. 3D.

FIG. 3F is a process sectional view following FIG. 3E.

FIG. 4A illustrates an example in which the density of a region low in transmittance increases stepwise from the center to the peripheral edge of a transmissive member.

FIG. 4B illustrates an example in which the transmittance continuously varies from the center to the peripheral edge of the transmissive member.

FIG. 5A is a sectional view illustrating a process of forming a lens at a transmissive member.

FIG. 5B is a process sectional view following FIG. 5A.

FIG. 5C is a process sectional view following FIG. 5B.

FIG. 5D is a process sectional view following FIG. 5C.

FIG. 5E is a process sectional view following FIG. 5D.

FIG. 5F is a process sectional view following FIG. 5E.

FIG. 6A is an explanatory view schematically illustrating an exemplary procedure of an imprinting process.

FIG. 6B is a process sectional view following FIG. 6A.

FIG. 7A is a sectional view illustrating a manufacturing process of a display device according to a second embodiment.

FIG. 7B is a process sectional view following FIG. 7A.

FIG. 7C is a process sectional view following FIG. 7B.

FIG. 7D is a process sectional view following FIG. 7C.

FIG. 7E is a process sectional view following FIG. 7D.

FIG. 7F is a process sectional view following FIG. 7E.

FIG. 8A is a sectional view illustrating a manufacturing process of a display device according to a third embodiment.

FIG. 8B is a process sectional view following FIG. 8A.

FIG. 8C is a process sectional view following FIG. 8B.

FIG. 8D is a process sectional view following FIG. 8C.

FIG. 8E is a process sectional view following FIG. 8D.

FIG. 8F is a process sectional view following FIG. 8E.

FIG. 9A is a sectional view illustrating a manufacturing process of a display device according to a fourth embodiment.

FIG. 9B is a process sectional view following FIG. 9A.

FIG. 9C is a process sectional view following FIG. 9B.

FIG. 9D is a process sectional view following FIG. 9C.

FIG. 9E is a process sectional view following FIG. 9D.

FIG. 9F is a process sectional view following FIG. 9E.

FIG. 9G is a process sectional view following FIG. 9F.

FIG. 10A is a sectional view of a step performed instead of those in FIGS. 9B and 9C.

FIG. 10B is a process sectional view following FIG. 10A.

FIG. 10C is a process sectional view following FIG. 10B.

FIG. 11A is a sectional view illustrating a manufacturing process of a display device according to a fifth embodiment.

FIG. 11B is a process sectional view following FIG. 11A.

FIG. 11C is a process sectional view following FIG. 11B.

FIG. 11D is a process sectional view following FIG. 11C.

FIG. 11E is a process sectional view following FIG. 11D.

FIG. 11F is a process sectional view following FIG. 11E.

FIG. 11G is a process sectional view following FIG. 11F.

FIG. 11H is a process sectional view following FIG. 11G.

FIG. 11I is a process sectional view following FIG. 11H.

FIG. 11J is a process sectional view following FIG. 11I.

FIG. 12 is a plan view of an electronic apparatus according to a sixth embodiment.

FIG. 13 illustrates a sectional structure of an imaging unit of a camera module with which an electronic apparatus is equipped according to a seventh embodiment.

FIG. 14 is a plan view of a capsule endoscope to which the electronic apparatus according to any of the first to seventh embodiments is applied.

FIG. 15 is a rear view of a digital single-lens reflex camera to which the electronic apparatus according to any of the first to seventh embodiments is applied.

FIG. 16A is a plan view illustrating an example in which the electronic apparatus 2 according to any of the first to seventh embodiments is applied to a head-mounted display (HMD).

FIG. 16B illustrates the current HMD.

### MODE FOR CARRYING OUT THE INVENTION

Hereinafter, embodiments of a display device will be described with reference to the drawings. Although main components of the display device will be mainly described below, such a display device 1 may have components and functions that are not illustrated or described. The following description does not exclude the components and functions that are not illustrated or described.

### First Embodiment

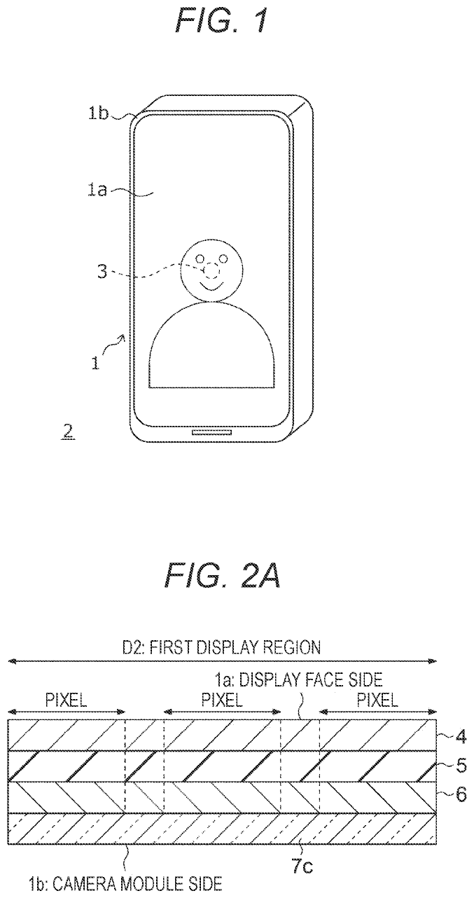

FIG. 1 is a schematic external view of an electronic apparatus 2 equipped with a display device 1 according to a first embodiment. The electronic apparatus 2 in FIG. 1 is any electronic apparatus 2 having both a display function and a shooting function, such as a smartphone, a mobile phone, a tablet, or a PC. The electronic apparatus 2 in FIG. 1 includes a camera module (imaging unit) 3 disposed opposite a display face 1a of the display device 1. In FIG. 1, the disposition place of the camera module 3 is indicated by a broken line. As described above, in the electronic apparatus 2 in FIG. 1A, the camera module 3 is provided on the rear side of the display face 1a of the display device 1. Therefore, the camera module 3 performs imaging through the display device 1. In the present specification, the display face 1a side of the display device 1 is referred to as a front face, and the side on which the camera module 3 is disposed is referred to as a rear face.

In the present embodiment, the transmittance of part of the display region overlapping the disposition place of the camera module 3 on the rear face side of the display device 1 is increased.

The display device 1 according to the present embodiment includes a first display region D1 and a second display region D2 disposed on a substrate. In the first display region D1, the substrate has a first transmittance. In the second display region D2, the substrate has a second transmittance higher than the first transmittance. The second display region D2 may face a sensing device such as the camera module 3 disposed on the side of the face opposite to the display face on the substrate.

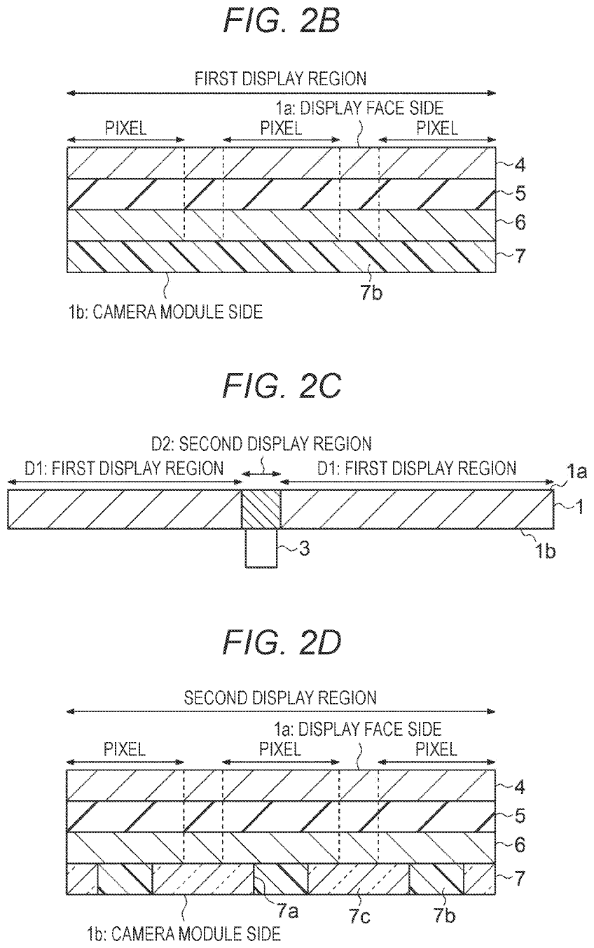

FIG. 2A is a schematic sectional view illustrating part of the second display region D2. FIG. 2B is a schematic sectional view illustrating part of the first display region D1. FIG. 2C is a schematic sectional view of the display device 1 including the first display region D1 and the second display region D2. FIGS. 2A and 2B each illustrate the region including three adjacent pixels. Each pixel has an upper electrode 4, a light emitting layer 5, and a lower electrode 6. In practice, such a pixel has a complicated layered configuration, but is illustrated in a simplified manner in FIGS. 2A and 2B. The upper face in FIGS. 2A and 2B is the display face 1a, and the camera module 3 is disposed on the lower face side.

As illustrated in FIG. 2B, a base film 7 is disposed under the lower electrode 6 in the first display region D1. The base film 7 includes opaque polyimide low in transmittance. Due to the low transmittance of the base film 7, light from the display face 1a side is blocked by the base film 7, resulting in a decrease in the amount of incident light to the camera module 3. Therefore, in the present embodiment, the base film 7 is not disposed under the lower electrode 6 in the second display region D2 as illustrated in FIG. 2A. In FIGS. 2A and 2B, the base film 7 is referred to as a first film 7b. FIG. 2A illustrates an example in which a second film 7c higher in transmittance than the base film 7 (first film 7b) is disposed under the lower electrode 6 in the second display region D2. As illustrated in FIG. 2C, the second display region D2 faces the camera module 3 disposed on the side of the face 1b opposite to the display face 1a on the substrate of the display device 1.

FIG. 2B illustrates the example in which the second film 7c is disposed under the lower electrode 6 over the entirety of the second display region D2. However, as illustrated in FIG. 2D, the first film 7b may be disposed under the lower electrode 6 in the second display region D2, an opening 7a may be partially provided at the first film 7b, and the second film 7c may be disposed within the opening 7a. The second film 7c in FIG. 2D is disposed on the side of the face 1b opposite to the display face 1a in at least part of the second display region D2, and the part includes a boundary portion between adjacent pixels within the second display region D2.

The opening 7a is provided at least at a boundary portion between pixels. For sufficient incident light to the camera module 3, the ratio of the area of the opening 7a or the second film 7c to the area of the light emitting region within the second display region D2 is desirably 30% or more.

As described later, the second film 7c may have a function of cutting infrared light. Further, the transmittance of the boundary portion between the first film 7b and the second film 7c may vary continuously or stepwise from the first film 7b to the second film 7c.

The first transmittance to visible light having a wavelength of 400 nm is 0 to 50%, for example. The second transmittance to the visible light is 51 to 100%, for example.

On the other hand, in the first display region D1, as illustrated in FIG. 2B, the base film 7 is also disposed at the boundary portion between pixels, and no opening is provided.

This arrangement enables a further increase in the transmittance on the camera module 3 side of the second display region D2 overlapping the disposition place of the camera module 3 and an increase in the amount of incident light to the camera module 3. As a result, the image quality of a shot image can be improved.

The display device 1 according to the present embodiment is characterized in that the transmittance on the camera module 3 side of the second display region D2 is further increased. Hereinafter, a configuration of the display device 1 according to the present embodiment and a manufacturing process thereof will be described. The display device 1 according to the present embodiment is applicable to a display device 1 including an organic electroluminescence (EL) element that performs self-light emission, and is also applicable to a liquid crystal display device 1.

Because a normal camera module 3 mainly images visible light, anything low in transmittance to visible light is often referred to as being opaque. However, in a case where the camera module 3 disposed on the rear face side of the display device 1 images, for example, infrared light, anything low in transmittance to infrared light is opaque.

Thus, the transparent or opaque level and the value of the transmittance are determined in consideration of a balance with the wavelength of light to which the camera module 3 disposed on the rear face side of the display device 1 has detection sensitivity. Hereinafter, mainly on the premise that the camera module 3 for detecting or imaging visible light is disposed on the rear face side of the display device 1, anything high in transmittance to visible light is referred to as being transparent, and anything low in transmittance to visible light is referred to as being opaque.

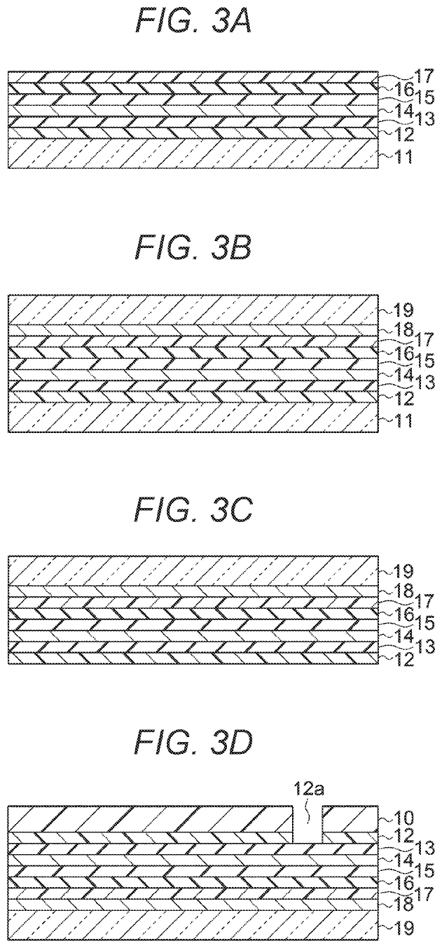

FIGS. 3A to 3F are sectional views illustrating a manufacturing process of the display device 1 according to the first embodiment. FIGS. 3A to 3F each illustrate a sectional structure of part of the second display region D2 in FIG. 2. FIGS. 3A to 3F each illustrate a layered configuration related to the characteristic portion of the display device 1 according to the present embodiment, and there may be a layer not illustrated in the actual display device 1. For example, most of the recent display devices 1 adopt a touch panel type, and a touch sensor layer is provided in the layered configuration of such a display device 1 as above, but is not given in FIGS. 3A to 3F. Further, in FIGS. 3A to 3F, although the light emitting layer 5 that causes the organic EL element to emit light is illustrated as an EL layer 15, the light emitting layer 5 can include a plurality of layers in practice. Furthermore, although a plurality of TFTs that controls light emission of the organic EL element is illustrated as a TFT layer 14, the TFT layer 14 can include a plurality of layers in practice.

First, as illustrated in FIG. 3A, a base film 12, a first protective film 13, a TFT layer 14, an EL layer 15, a second protective film 16, and transparent film 17 are formed in this order on a glass substrate 11. The base film 12 functions as a sealing material, and usually includes opaque polyimide excellent in heat resistance. The first protective film 13 includes an insulating film high in transmissivity, such as SiN or SiO₂. The TFT layer 14 is formed by implanting impurity ions into, for example, the drain region and the source region, and thermally diffusing the impurity ions. In practice, the EL layer 15 includes a plurality of layers such as an electron injection layer, an electron import layer, a light emitting layer 5, a hole transport layer, a charge generation layer, and an electron import layer. The second protective film 16 includes an insulating film high in transmissivity, such as SiN or SiO₂. The step of FIG. 3A is the same as that of a normal organic EL display device 1.

Among the layers illustrated in FIG. 3A, the opaque layer is the base film 12, and the other layers (excluding a sacrificial layer) each include a material higher in transmittance than the base film 12.

Next, as illustrated in FIG. 3B, a glass substrate 19 is formed above the transparent film 17 with the sacrificial layer 18 interposed therebetween. The sacrificial layer 18 is provided for absorbing laser light to facilitate peeling of the glass substrate 19 in peeling of the glass substrate 19 by laser lift-off in a later step.

Next, as illustrated in FIG. 3C, the glass substrate 11 on the base film 12 is removed to expose the base film 12. The glass substrate 11 may be removed by backgrinding (BGR) or chemical mechanical polishing (CMP). Alternatively, the glass substrate 11 may be peeled off by laser lift-off.

Next, as illustrated in FIG. 3D, a resist 10 is applied onto the exposed base film 12 with the front and rear sides reversed, and then the resist 10 is patterned by lithography. More specifically, an opening 12a is provided at the resist 10 so as to be coincident with the disposition place of a camera module 3. Then, using the resist 10 as a mask, part of the base film 12 at the opening 12a of the resist 10 is etched.

Next, as illustrated in FIG. 3E, the resist 10 is peeled off to expose the base film 12. At the part of the base film 12 (region overlapping the disposition place of the camera module 3) is cut by the etching and the opening 12a is formed. A transmissive member 20 is formed at the opening 12a. The transmissive member 20 may be, for example, transparent polyimide. Note that the transmissive member 20 corresponds to the second film 7c and the base film 12 corresponds to the first film 7b in FIG. 2.

As described above, transparent polyimide is often inferior in heat resistance to the existing opaque polyimide. However, in the present embodiment, only the portion overlapping the camera module 3 includes transparent polyimide. Because the base film 12 itself has heat resistance, a diffusion process can be performed with high heat. Thus, there is no possibility that the electrical characteristics of the TFT formed in the TFT layer 14 are deteriorated.

After the step of FIG. 3E, as illustrated in FIG. 3F, the glass substrate 19 is peeled off by laser lift-off. The laser light emitted to the glass substrate 19 is absorbed by the sacrificial layer 18, and the glass substrate 19 formed on the sacrificial layer 18 can be easily peeled off. As a result, a flexible substrate-shaped display device 1 excellent in flexibility is obtained. Because the display device 1 can be used in a curved shape, its utility value is increased.

After the step of FIG. 3F, the camera module 3 can be attached facing the transmissive member 20 formed at the part of the base film 12. Note that, as described later, various sensor modules other than the camera module 3 may be attached to the rear face side of the display device 1 according to the present embodiment. For example, various biometric-information detection sensors such as a fingerprint sensor may be disposed facing the transmissive member 20 at the base film 12. Hereinafter, structure bodies including the camera module 3 that perform any type of sensing will be collectively referred to as a sensing device.

In the display device 1 fabricated in the manufacturing process of FIGS. 3A to 3F, the transmittance (second transmittance) on the sensing device side of the transmissive member 20 formed at the part of the base film 12 is higher than the transmittance (first transmittance) on the sensing device side of the base film 12. The transmissive member 20 formed at the part of the base film 12 can be formed at a boundary portion between pixels of the display device 1. In the present specification, a display region not facing the sensing device is referred to as a first display region D1, and a display region facing the sensing device is referred to as a second display region D2. The transmittance on the side of the face opposite to a display face 1a in the first display region D1 is the first transmittance, and the transmittance on the side of the face (sensing device side) opposite to the display face 1a in the second display region D2 is the second transmittance higher than the first transmittance.

The transmissive member 20 may have not only higher transmittance than the base film 12 but also a function of cutting infrared light. If the transmissive member 20 has a function of cutting infrared light, it is not necessary to provide an infrared-light cut film or the like on the sensing device side, so that the configuration of the sensing device can be simplified.

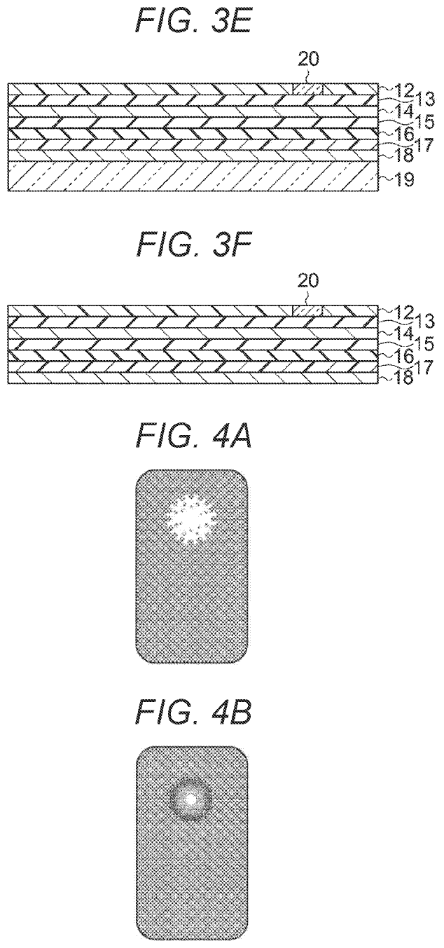

In a case where the respective transmittances of the base film 12 and the transmissive member 20 are greatly different from each other, there is a possibility that the boundary between the base film 12 and the transmissive member 20 is visually recognized through the display face 1a. Therefore, as illustrated in FIG. 4A or FIG. 4B, the transmittance of the boundary portion between the base film 12 and the transmissive member 20 may vary continuously or stepwise from the base film 12 to the transmissive member 20. In FIGS. 4A and 4B, a location low in transmittance is represented in black. FIG. 4A illustrates an example in which the density of a region low in transmittance increases stepwise from the center to the peripheral edge of the transmissive member 20. FIG. 4B illustrates an example in which the transmittance continuously varies from the center to the peripheral edge of the transmissive member 20.

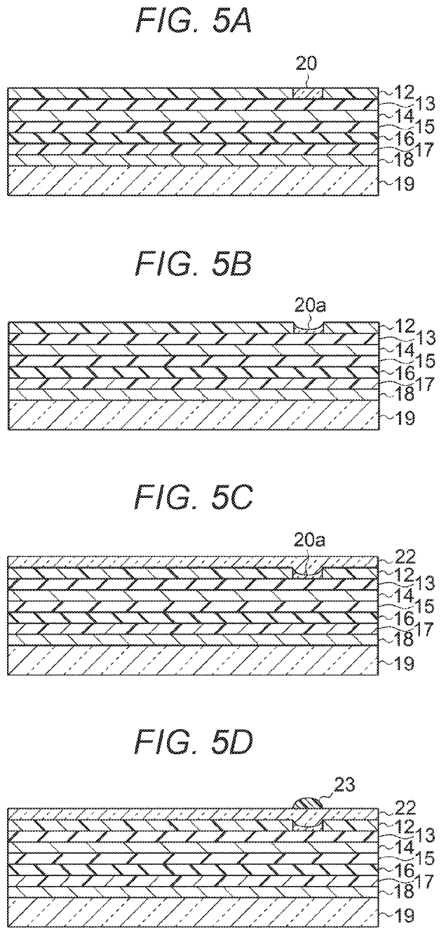

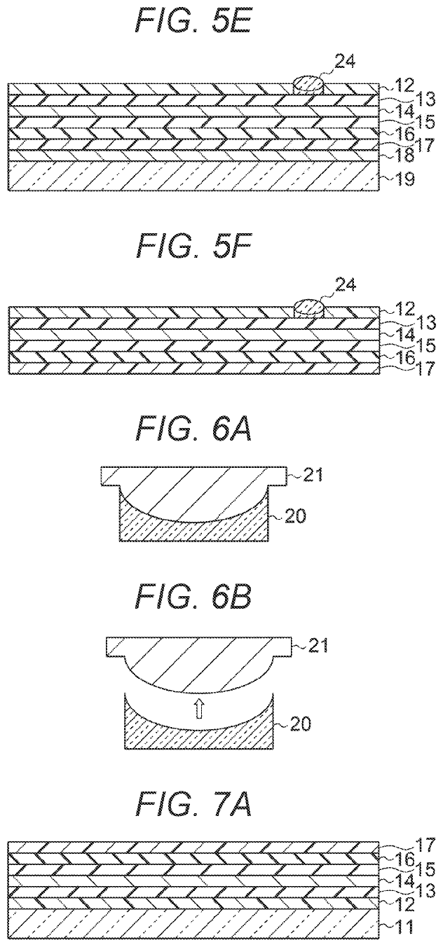

For example, a lens for the camera module 3 can be formed at the transmissive member 20 manufactured in the steps of FIGS. 3A to 3E. FIGS. 5A to 5F are sectional views illustrating a process of forming a lens at the transmissive member 20. FIG. 5A illustrates a sectional structure similar to that in FIG. 3E. Next, as illustrated in FIG. 5B, part of the transmissive member 20 formed at the part of the base film 12 is removed to form a concave portion 20a. The concave portion 20a can be formed by, for example, etching or imprinting. FIGS. 6A and 6B are explanatory views schematically illustrating an exemplary procedure of an imprinting process. First, as illustrated in FIG. 6A, under pressing with a master plate 21 for imprinting, the front face of the transmissive member 20 is subjected to heating or is irradiated with light, so that the outer shape of the master plate 21 is transferred to the transmissive member 20. Next, the master plate 21 is released, and heat treatment, light irradiation, or the like is performed. As a result, the front-face shape of the transmissive member 20 can be formed into a shape corresponding to the outer shape of a lens.

In such a manner, the imprinting process is performed to form at least one of a concave portion or a convex portion on the front face of the transmissive member 20.

After the step of FIG. 5B is completed, next, as illustrated in FIG. 5C, a transparent resin layer 22 is formed on the base film 12 including the inside of the above concave portion 20a in a process similar to a manufacturing process of an on-chip lens of a complementary metal oxide semiconductor (CMOS) image sensor.

Next, as illustrated in FIG. 5D, a resist 23 is applied onto the transparent resin layer 22 and patterned to leave the resist 23 only immediately above the transmissive member 20. Next, as illustrated in FIG. 5E, the transparent resin layer 22 is partially removed by etching using the resist 23 as a mask, and then the resist 23 is removed. As a result, a lens 24 includes the transparent resin layer 22 at the part of the transmissive member 20. The lens 24 is, for example, a convex lens. The transmissive member 20 is subjected to the front-face processing in FIG. 5B and the resist 23 is patterned in FIG. 5D so as to fit the outer shape of the lens 24. Thus, a lens having a desired outer shape can be formed.

Next, as illustrated in FIG. 5F, similarly to FIG. 3F, the glass substrate 19 is peeled off by, for example, laser lift-off, so that a flexible substrate-shaped display device 1 with the lens is obtained. This lens can be used to collect light to a sensing device such as the camera module 3.

In FIGS. 5A to 5F, the example in which the front face of the transmissive member 20 is processed to form the convex lens has been described. The transmissive member 20, however, can be processed into various shapes by using, for example, an imprinting process. For example, the transmissive member 20 can also be processed to form a moth-eye structure layer having fine bumps. The moth-eye structure layer has a function of suppressing reflection. Thus, for example, due to disposition of the moth-eye structure layer between the light emitting layer 5 and the lens of the camera module 3, the amount of incident light to the lens can be increased and a shot image quality can be improved.

As described above, in the first embodiment, the opening 12a is provided at the part of the base film 12 including opaque polyimide so as to be coincident with the disposition place of the sensing device such as the camera module 3, and the transmissive member 20 is formed at the opening 12a. Therefore, sufficient light can be guided to the sensing device through the transmissive member 20, so that the detection sensitivity of the sensing device can be improved.

### Second Embodiment

In the first embodiment, the transmissive member 20 is formed at the opening 12a formed at the part of the base film 12, but the opening 12a may be left. Even if the opening 12a is left, that is, the transmissive member 20 is not disposed inside the opening 12a, the transmittance on the sensing device side of the opening 12a is higher than the transmittance on the sensing device side of the base film 12. Therefore, due to disposition of the sensing device facing the opening 12a, the amount of incident light to the sensing device is increased.

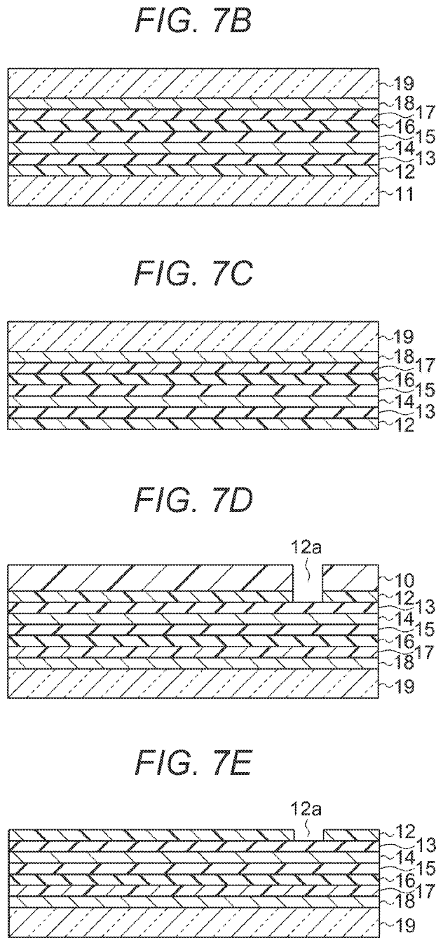

FIGS. 7A to 7F are sectional views illustrating a manufacturing process of a display device 1 according to a second embodiment. FIGS. 7A to 7D are the same as FIGS. 3A to 3D. In FIG. 3E, the opening 12a is formed at the exposed base film 12 so as to be coincident with the disposition place of the sensing device, and the transmissive member 20 is formed at the opening 12a. However, in FIG. 7E, an opening 12a is formed and left, and a transmissive member 20 is not formed within the opening 12a. Next, as illustrated in FIG. 7F, a glass substrate 19 is peeled off by laser lift-off, so that a flexible substrate-shaped display device 1 excellent in flexibility can be obtained.

After the step of FIG. 7F, a sensing device such as a camera module 3 may be disposed facing the opening 12a formed at part of the base film 12, or in order to protect a base film 12, the front face of the base film 12 may be covered with a protective film having transmissivity while leaving the opening 12a. In this case, the opening 12a becomes a void sealed with the base film 12 and the protective film, so that high transmissivity is maintained.

As described above, in the second embodiment, the opening 12a is formed at the part of the base film 12 so as to be coincident with the disposition place of the sensing device. Thus, sufficient light can be incident to the sensing device through the opening 12a. Because the step of forming another member at the opening 12a can be omitted, the manufacturing process can be simplified as compared with the first embodiment.

### Third Embodiment

In a third embodiment, a base film 12 including polyimide is removed after the process of applying heat in fabrication of a display device 1 is completed.

The reason for using opaque polyimide as the base film 12 of a display device 1 is that opaque polyimide is excellent in heat resistance. In the display device 1, it is necessary to form a TFT layer 14 using polysilicon or the like, and diffusion treatment of impurity ions is essential for the formation of the TFT layer 14. In the diffusion treatment, heat treatment is performed. Thus, for example, in a case where transparent polyimide is used as a base film 12, too high heat cannot be applied thereto. Thus, there is a possibility that the electrical characteristics of the TFT are deteriorated.

Therefore, in the present embodiment, the base film 12 using opaque polyimide is formed until the step of applying heat in the fabrication of the display device 1 is completed, and the base film 12 is peeled off after the step of applying heat is completed.

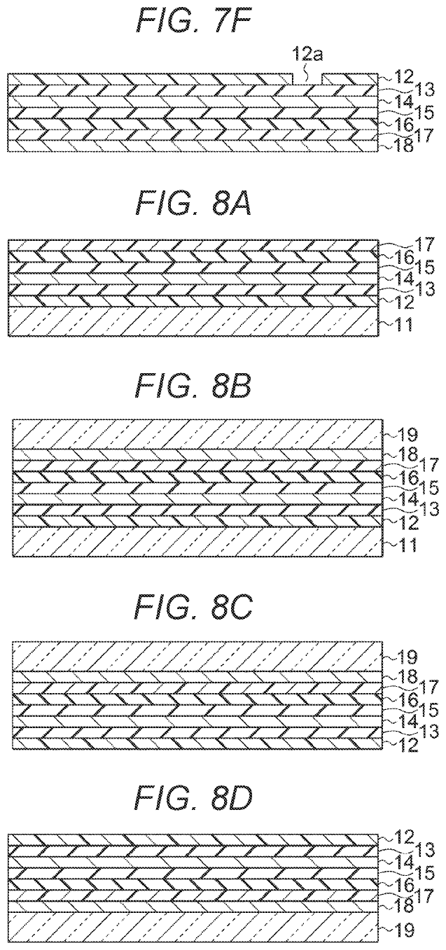

FIGS. 8A to 8F are sectional views illustrating a manufacturing process of the display device 1 according to the third embodiment. FIGS. 8A to 8C are the same as FIGS. 3A to 3C. As illustrated in FIG. 8D, at the stage where a glass substrate 11 is removed (peeled off) to expose the base film 12, a TFT layer 14 and an EL layer 15 are already formed. Thus, there is no subsequent step of applying high heat. Therefore, as illustrated in FIG. 8E, the base film 12 is removed by etching or the like. At this time, a protective film including, for example, SiN is used as an etching stopper layer. Next, as illustrated in FIG. 8F, a glass substrate 19 is peeled off by laser lift-off.

In a case where the protective function and sealing function of the display device 1 become insufficient due to the removal of the base film 12, a transparent resin layer 22 or the like may be disposed on the protective film.

As described above, in the third embodiment, the base film 12 including opaque polyimide is formed until the step of applying heat in the fabrication of the display device 1 is completed, and the base film 12 is removed after the step of applying heat is completed. In such a manner, the transmittance of the entirety of a second display region D2 can be increased, so that sufficient light can be incident to a sensing device.

### Fourth Embodiment

A fourth embodiment is different from the first to third embodiments in the order of steps of forming an opening 12a at part of a base film 12.

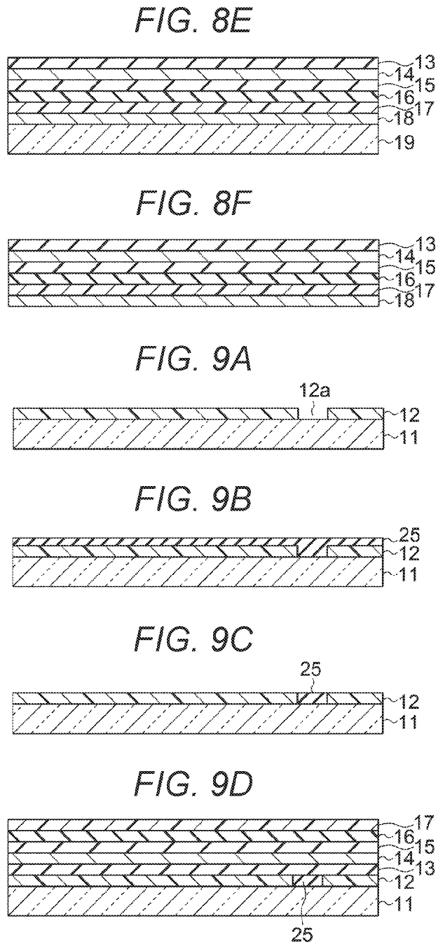

FIGS. 9A to 9G are sectional views illustrating a manufacturing process of a display device 1 according to the fourth embodiment. First, as illustrated in FIG. 9A, the base film 12 including opaque polyimide is formed on a glass substrate 11, and then the opening 12a is formed at the base film 12 so as to be coincident with the disposition place of a sensing device. Here, for example, a resist is applied onto the base film 12 and patterned, and the opening 12a is formed by etching.

Next, as illustrated in FIG. 9B, the upper face of the base film 12 including the inside of the opening 12a is covered with an insulating film 25 high in transmissivity, such as SiO₂ or SiN. Next, as illustrated in FIG. 9C, the insulating film 25 formed on the upper face of the base film 12 is removed by, for example, CMP to expose the base film 12 and the insulating film 25 within the opening 12a.

Next, as illustrated in FIG. 9D, a first protective film 13, a TFT layer 14, an EL layer 15, a second protective film 16, and a transparent film 17 are formed in this order on the base film 12.

Next, as illustrated in FIG. 9E, the glass substrate 11 is removed (peeled off) by, for example, etching or laser lift-off to expose the base film 12.

Next, as illustrated in FIG. 9F, the insulating film 25 formed inside the opening 12a of the base film 12 is removed by, for example, etching. At this time, the second protective film 16 under the base film 12 functions as an etching stopper layer.

Next, as illustrated in FIG. 9G, the entire upper face of the base film 12 including the inside of the opening 12a is covered with a transmissive member 20. As a result, a flexible substrate-shaped display device 1 is obtained.

In FIGS. 9A to 9G, the opening 12a is formed within the base film 12 at the initial stage of the manufacturing process of the display device 1. With the insulating film 25 high in heat resistance formed within the opening 12a, the layers of the display device 1 are each formed in the above order. Finally, the insulating film 25 within the opening 12a is replaced with the original transmissive member 20.

In the above step of FIG. 9C, the insulating film 25 is removed by, for example, CMP to expose the base film 12 and the insulating film 25 within the opening 12a. A stopper layer may be provided in advance on the upper face of the base film 12.

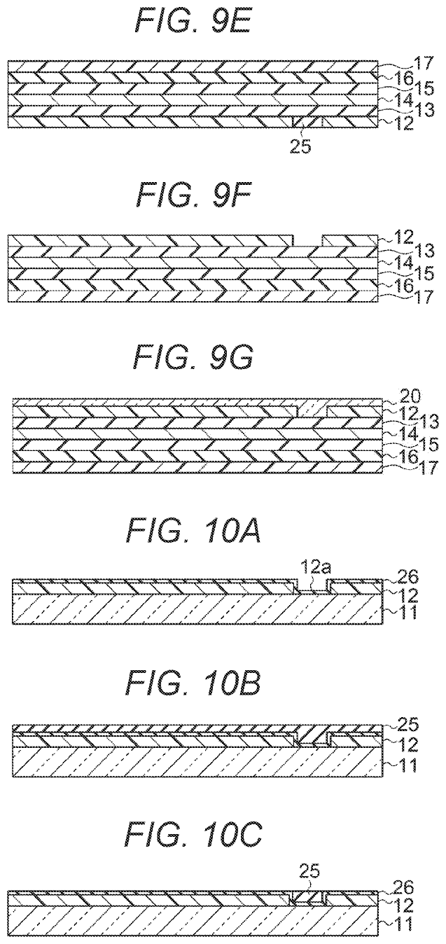

FIGS. 10A to 10C are sectional views of steps performed instead of those of FIGS. 9B and 9C. First, as illustrated in FIG. 9A, an opening 12a is formed at part of a base film 12. Then, as illustrated in FIG. 10A, the upper face of the base film 12 including an inner wall portion of the opening 12a is covered with a stopper layer 26. The stopper layer 26 is formed by, for example, atomic layer deposition (ALD), or chemical vapor deposition (CVD).

Next, as illustrated in FIG. 10B, an insulating film 25 is formed on the stopper layer 26. Next, the insulating film 25 on the stopper layer 26 is removed by etching to expose the stopper layer 26 and the insulating layer 25 within the opening 12a.

As described above, in the fourth embodiment, the opening 12a is formed at the base film 12 at the initial stage of the manufacturing process of the display device 1. Thus, it is not necessary to dispose an etching stopper layer 26 or the like under the base film 12, and the opening 12a can be formed easily. Further, the temporary insulating film 25 high in heat resistance is formed at the opening 12a and the insulating film 25 is replaced with the transmissive member 20 at the final stage. Thus, high heat can be applied at the time of manufacturing the display device 1, so that the display device 1 excellent in electrical characteristics can be fabricated.

### Fifth Embodiment

In the display device 1 according to any of the first to fourth embodiments described above, various sensing devices can be disposed facing the opening 12a formed at the part of the base film 12. Hereinafter, an example in which a fingerprint sensor that does not require a lens is disposed will be described as an exemplary sensing device for detecting biometric information.

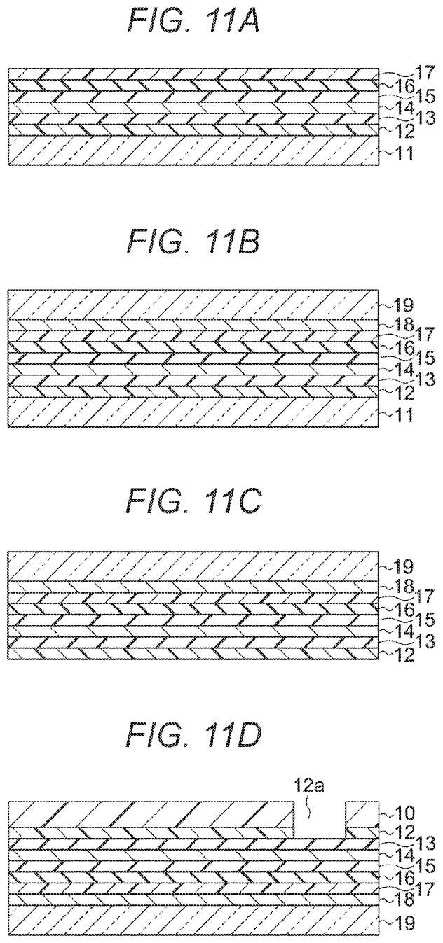

FIGS. 11A to 11J are sectional views illustrating a manufacturing process of a display device 1 according to a fifth embodiment. FIGS. 11A to 11E are similar to FIGS. 7A to 7E. However, in the present embodiment, it is assumed that a fingerprint sensor 31 is disposed. Thus, the opening size of an opening 12a formed at part of a base film 12 is a size in agreement with the outer shape of the fingerprint sensor 31. More specifically, the opening size of the opening 12a needs to be larger than the outer size of the fingerprint sensor 31.

Next, as illustrated in FIG. 11F, the fingerprint sensor 31 is formed within the opening 12a formed at the part of the base film 12. The fingerprint sensor 31 does not require a lens on its outside, but an inner lens 31a is provided inside the fingerprint sensor 31.

As described above, the opening size of the opening 12a formed at the part of the base film 12 is larger than the outer size of the fingerprint sensor 31. Thus, when the fingerprint sensor 31 is disposed inside the opening 12a, a gap is formed between the inner wall face of the opening 12a and the outer wall face of the fingerprint sensor 31. Therefore, as illustrated in FIG. 11G, an adhesive layer or an insulating film 32 is formed on the entire upper face of the base film 12 including the gap. The insulating film 32 in this case is, for example, SiO₂ or SiN.

Next, as illustrated in FIG. 11H, the adhesive layer or the insulating film 32 is removed by, for example, CMP or etching to expose the base film 12. As a result, the adhesive layer or the insulating film 32 fills between the inner wall face of the opening 12a and the outer wall face of the fingerprint sensor 31.

Next, as illustrated in FIG. 11I, the adhesive layer or the insulating film 32 formed on a pad portion 33 of the fingerprint sensor 31 is removed by lithography and etching to expose the pad portion 33. Next, as illustrated in FIG. 11J, a bonding wire 34 is connected to the pad portion 33 of the fingerprint sensor 31 to make wiring connection.

As described above, in the fifth embodiment, the sensing device can be directly disposed at the opening 12a formed at the part of the base film 12.

### Sixth Embodiment

In a sixth embodiment, a plurality of sensing devices is disposed opposite a display face 1a of a display device 1.

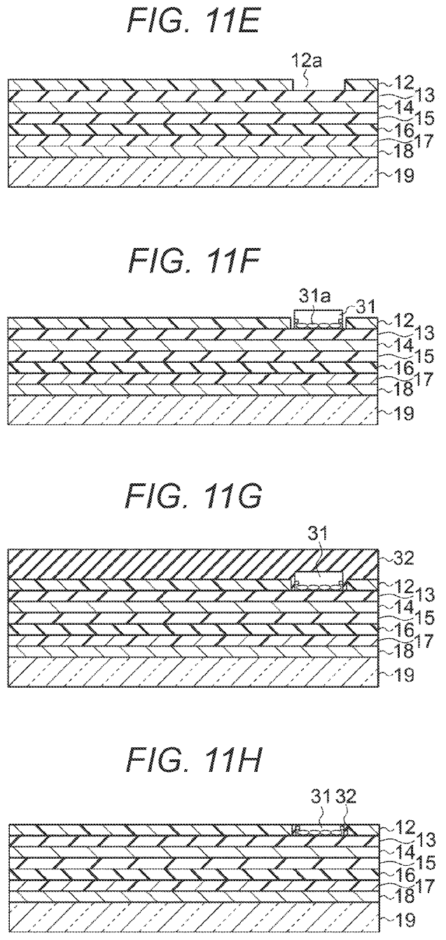

FIG. 12 is a plan view of an electronic apparatus 2 according to the sixth embodiment. In the electronic apparatus 2 in FIG. 12, three sensing devices 30 are disposed opposite the display face 1a of the display device 1. Note that the number of sensing devices 30 is not limited to three. Further, a target to be sensed by such a sensing device 30 described above is optional. For example, all the three sensing devices 30 may be camera modules and different in focal length. Alternatively, a camera module and two biometric-information-detection sensing devices may be disposed in combination.

An opening 12a is formed at a base film 12 of the display device 1 corresponding to each of the sensing devices 30. A transmissive member 20 may be disposed at the opening 12a, or may be left. There is a possibility that the optimum light amount of incident light differs depending on the type of a sensing device 30. Thus, in order to dispose a transmissive member 20 at the opening 12a, it is desirable to set the transmittance of the transmissive member 20 to a value corresponding to each sensing device 30.

As described above, in the sixth embodiment, the plurality of types of sensing devices 30 is disposed on the rear face side of the display device 1, and the transmittance of the transmissive member 20 disposed at a place overlapping each sensing device 30 is optimized individually. As a result, the detection sensitivity of all the sensing devices 30 can be improved.

### Seventh Embodiment

In an electronic apparatus 2 according to a seventh embodiment, an optical system of a camera module 3 is different from those of the first to sixth embodiments.

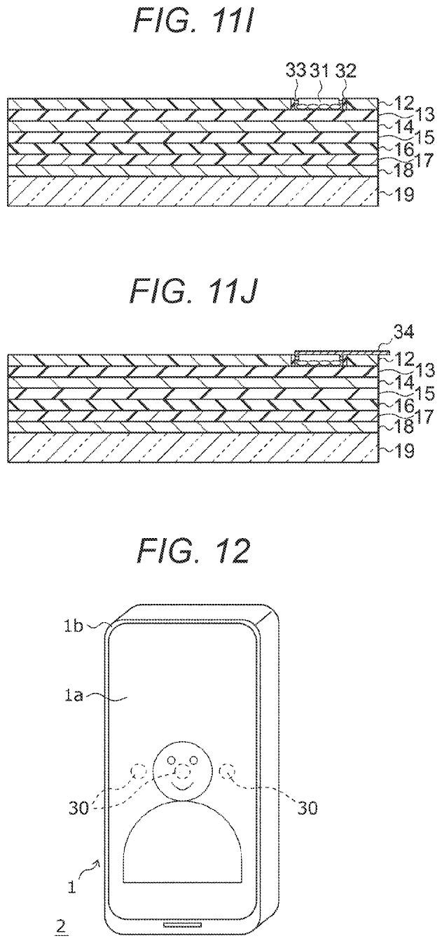

FIG. 13 illustrates a sectional structure of an imaging unit of the camera module 3 with which the electronic apparatus 2 according to the seventh embodiment is equipped. The imaging unit in FIG. 13 includes a microlens array 64 that is not a single lens or a lens group including each single lens arranged in its optical axis direction.

More specifically, the imaging unit in FIG. 13 includes a photoelectric conversion unit 4a disposed along the bottom face of a casing 63, the microlens array 64 disposed above the photoelectric conversion unit 4a, a plurality of light blocking bodies 66 disposed between adjacent microlenses 65, and a light guide plate 67 disposed above the microlens array 64. The imaging unit in FIG. 13 is applicable to any of the first to eighth embodiments described above.

### Eighth Embodiment

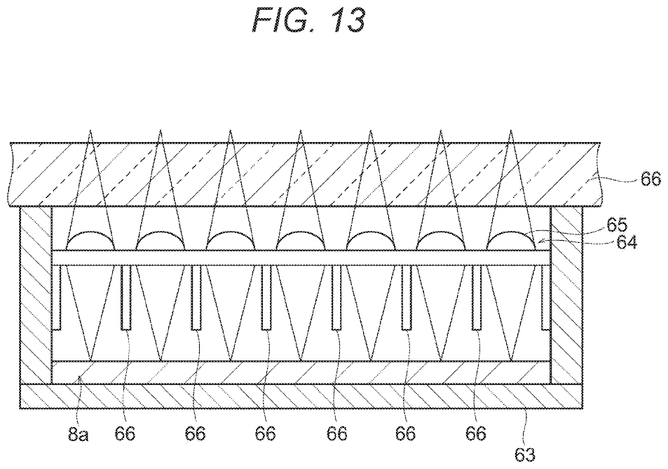

As a specific candidate for the electronic apparatus 2 having the configuration described in any of the first to seventh embodiments, various candidates are conceivable. For example, FIG. 14 is a plan view of a capsule endoscope 50 to which the electronic apparatus 2 according to any of the first to seventh embodiments is applied. The capsule endoscope 50 in FIG. 14 includes, in a casing 51 having, for example, hemispherical both end faces and a cylindrical central portion, a camera (ultra-small camera) 52 for shooting an image of the inside of a body cavity, a memory 53 for recording data of the image shot by the camera 52, and a wireless transmitter 55 for transmitting the recorded data of the image to the outside through an antenna 54 after the capsule endoscope 50 is discharged to the outside of the subject.

Further, within the casing 51, a central processing unit (CPU) 56 and a coil (magnetic force/current conversion coil) 57 are provided. The CPU 56 controls shooting by the camera 52 and data accumulation operation into the memory 53, and controls data transmission from the memory 53 to a data receiving device (not illustrated) outside the casing 51 by the wireless transmitter 55. The coil 57 supplies power to the camera 52, the memory 53, the wireless transmitter 55, the antenna 54, and a light source 52b to be described later.

Further, the casing 51 is provided with a magnetic (reed) switch 58 for sensing setting in the setting of the capsule endoscope 50 in the data receiving device. The CPU 56 supplies power from the coil 57 to the wireless transmitter 55 at the time when the reed switch 58 senses the setting to the data receiving device and data transmission becomes possible.

The camera 52 includes, an imaging element 52a, for example, including an objective optical system for shooting an image of the inside of a body cavity and a plurality of light sources 52b for illuminating the inside of the body cavity. Specifically, the camera 52 includes, as such a light source 52b described above, for example, a complementary metal oxide semiconductor (CMOS) sensor provided with a light emitting diode (LED), or a charge coupled device (CCD).

The display device 1 in the electronic apparatus 2 according to any of the first to seventh embodiments is a concept including a light emitter such as the light source 52b in FIG. 14. The capsule endoscope 50 in FIG. 14 includes two light sources 52b, for example. These light sources 52b, however, can be configured by a display panel having a plurality of light source units or an LED module having a plurality of LEDs. In this case, disposition of an imaging unit of the camera 52 below the display panel or the LED module reduces restrictions on the layout of the camera 52, results in achievement of a capsule endoscope 50 smaller in size.

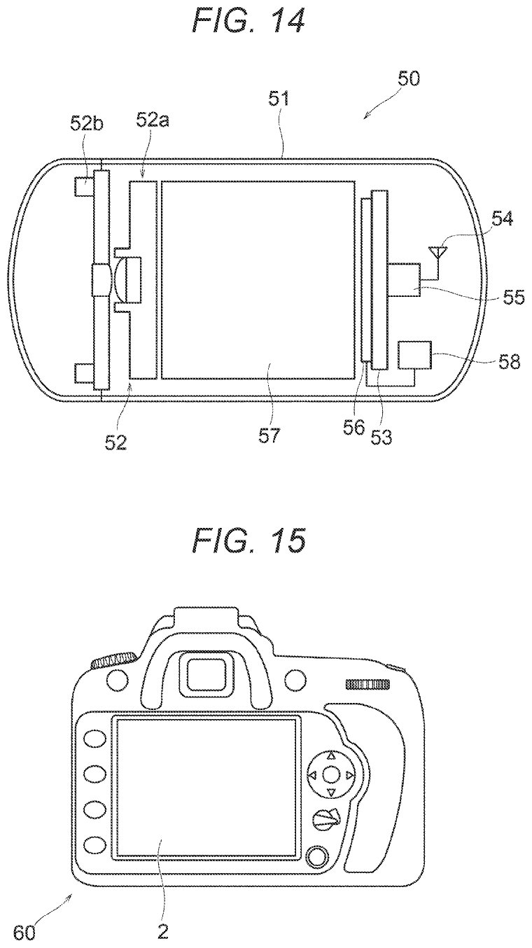

Further, FIG. 15 is a rear view of a digital single-lens reflex camera 60 to which the electronic apparatus 2 according to any of the first to seventh embodiments is applied. The digital single-lens reflex camera 60 or a compact camera includes a display device 1 for displaying a preview screen on the rear face opposite the lens. A camera module 3 may be disposed opposite a display face of the display device 1 such that a facial image of the shooter can be displayed on the display face 1a of the display device 1. In the electronic apparatus 2 according to any of the first to seventh embodiments, the camera module 3 can be disposed in the region overlapping the display device 1. Thus, it is not necessary to provide the camera module 3 in the frame portion of the display device 1, and the size of the display device 1 can be increased as much as possible.

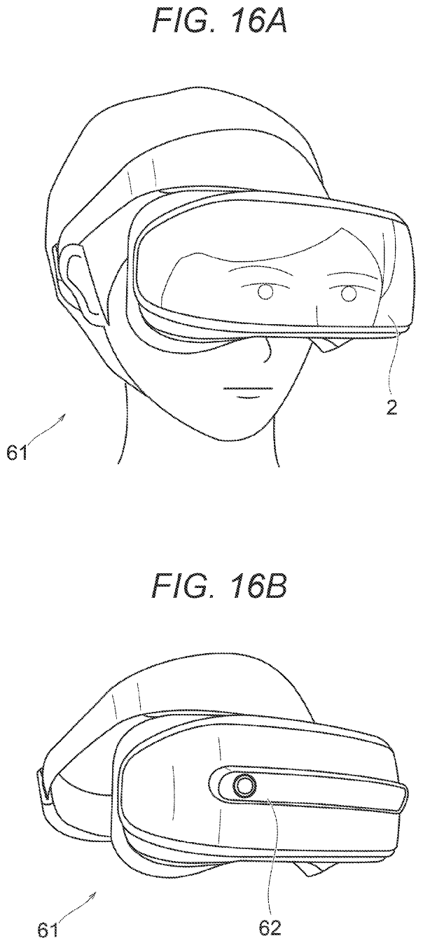

FIG. 16A is a plan view illustrating an example in which the electronic apparatus 2 according to any of the first to seventh embodiments is applied to a head-mounted display (HMD) 61. The HMD 61 in FIG. 16A is used for virtual reality (1R), augmented reality (AR), mixed reality (MR), substituional reality (SR), or the like. As illustrated in FIG. 16B, the current HMD is equipped with a camera 62 on its outer front face. Thus, there is a disadvantage that the wearer of the HMD can visually recognize the surrounding image but a person around the wearer cannot recognize the eyes or facial expression of the wearer of the HMD.

Therefore, in FIG. 16A, a display face of a display device 1 is provided on the outer front face of the HMD 61, and a camera module 3 is provided opposite the display face of the display device 1. As a result, the facial expression of the wearer shot by the camera module 3 can be displayed on the display face of the display device 1, and the person around the wearer can grasp the facial expression and eye movement of the wearer in real time.

In the case of FIG. 16A, the camera module 3 is provided on the rear face side of the display device 1. Thus, there is no restriction on the installation place of the camera module 3, resulting in an increase in the degree of freedom in the design of the HMD 61. Further, the camera can be disposed at an optimum position. Thus, it can prevent problems such as misalignment of the eyes of the wearer displayed on the display face.

As described above, in the eighth embodiment, the electronic apparatus 2 according to any of the first to seventh embodiments can be used for various applications, and its utility value can be increased.

Note that the present technology can also adopt the following configurations.

(1) A display device including:

a substrate;

a first display region disposed on the substrate, the first display region having a plurality of pixels; and

a second display region disposed on the substrate, the second display region having a plurality of pixels,

in which the substrate has a first transmittance in the first display region, and

the substrate has a second transmittance in the second display region higher than the first transmittance.

(2) The display device according to (1), in which the second display region faces a sensing device disposed on a side of a face opposite to a display face on the substrate.

(3) The display device according to (2), further including: a first film disposed on the side of the face opposite to the display face within the first display region, the first film having the first transmittance.

(4) The display device according to (3), further including: a second film disposed on the side of the face opposite to the display face within the second display region, the second film having the second transmittance.

(5) The display device according to (4), in which the second film is disposed on the side of the face opposite to the display face in at least part of the second display region, the part including a boundary portion between adjacent pixels within the second display region.

(6) The display device according to (4) or (5), in which a ratio of an area of the second film to an area of a light emitting region within the second display region is 30% or more.

(7) The display device according to any one of (4) to (6), in which the second film has a function of cutting infrared light.

(8) The display device according to any one of (4) to (7),

in which the second film is disposed at an opening formed by removal of part of the first film, and

a transmittance of a boundary portion between the first film and the second film varies continuously or stepwise from the first film to the second film.

(9) The display device according to any one of (4) to (8),

in which the first film contains polyimide, and

the second film contains a material higher in transmittance than the polyimide of the first film.

(10) The display device according to any one of (4) to (9), in which the second film has at least one of a concave portion or a convex portion.

(11) The display device according to (10), further including: an optical lens including the second film.

(12) The display device according to (10), further including: a moth-eye structure layer including the second film.

(13) The display device according to any one of (3) to (12),

in which the first film is provided in at least part of the second display region, the at least part excluding a boundary portion between adjacent pixels within the second display region, and

an opening of the first film is provided at the boundary portion between the adjacent pixels within the second display region.

(14) The display device according to any one of (1) to (13),

in which the first transmittance to visible light having a wavelength of 400 nm is 0 to 50%, and

the second transmittance to the visible light is 51 to 100%.

(15) An electronic apparatus including:

a display device; and

a sensing device disposed opposite a display face of the display device,

in which the display device includes:

a substrate;

a first display region disposed on the substrate, the first display region having a plurality of pixels; and

a second display region disposed on the substrate, the second display region having a plurality of pixels,

the substrate has a first transmittance in the first display region, and

the substrate has a second transmittance in the second display region higher than the first transmittance.

(16) The electronic apparatus according to (15), in which the sensing device includes an imaging sensor.

(17) The electronic apparatus according to (15), in which the sensing device includes a biometric-information detection sensor.

(18) The electronic apparatus according to any one of (15) to (17),

in which a plurality of the second display regions is provided on the display face, and

a plurality of the sensing devices is disposed corresponding to the plurality of the second display regions.

(19) The electronic apparatus according to (18), in which the respective second transmittances of at least two of the plurality of the second display regions are different from each other.

(20) A method for manufacturing a display device, the method including:

forming a first film having a first transmittance on a first support substrate;

forming a light emitting layer on the first film;

forming a protective film on the light emitting layer;

forming a second support substrate on the protective film;

removing the first support substrate; and

forming an opening at the first film in accordance with a disposition place of a sensing device.

(21) The method according to (20), further including: forming a second film at the opening, the second film having a second transmittance higher than the first transmittance.

(22) A manufacturing method including:

forming a first film having a first transmittance on a support substrate;

forming an opening at the first film so as to be coincident with a disposition place of a sensing device;

filling the opening with an insulating member;

forming a first protective film on the first film;

forming a light emitting layer on the first protective film;

forming a second protective film on the light emitting layer; and

removing the insulating member to form the opening at the first film.

(23) The method according to (22), further including: forming a second film at the opening formed by the removing, the second film being higher in transmittance than the first film.

Aspects of the present disclosure are not limited to the above individual embodiments, but include various modifications conceivable by those skilled in the art, and the effects of the present disclosure are not limited to the above details. That is, various additions, modifications, and partial deletions can be made without departing from the conceptual idea and spirit of the present disclosure derived from the details defined in the claims and equivalents thereof.

### REFERENCE SIGNS LIST

1 Display device
1a Display face
2 Electronic apparatus
3 Camera module
4 Upper electrode
5 Light emitting layer
6 Lower electrode
7 Base film
7a Opening
7b First film
7c Second film
10 Resist
11 Glass substrate
12 Base film
13 First protective film
14 TFT layer
15 EL layer
16 Second protective film
17 Transparent film
18 Sacrificial layer
19 Glass substrate
20 Transmissive member
20a Concave portion
21 Master plate
22 Transparent resin layer
23 Resist
24 Lens
25 Insulating film
26 Stopper layer
31 Fingerprint sensor
31a Inner lens
32 Adhesive layer or insulating film
33 Pad portion
34 Bonding wire
50 Capsule endoscope
51 Casing
52 Camera
53 Memory
54 Antenna
55 Wireless transmitter
60 Digital single-lens camera
61 Head-mounted display
64 Microlens array
65 Microlens
66 Light blocking body

1. A display device comprising:
a substrate;
a first display region disposed on the substrate, the first display region having a plurality of pixels; and
a second display region disposed on the substrate, the second display region having a plurality of pixels,
wherein the substrate has a first transmittance in the first display region, and
the substrate has a second transmittance in the second display region higher than the first transmittance.

2. The display device according to claim 1, wherein the second display region faces a sensing device disposed on a side of a face opposite to a display face on the substrate.

3. The display device according to claim 2, further comprising: a first film disposed on the side of the face opposite to the display face within the first display region, the first film having the first transmittance.

4. The display device according to claim 3, further comprising: a second film disposed on the side of the face opposite to the display face within the second display region, the second film having the second transmittance.

5. The display device according to claim 4, wherein the second film is disposed on the side of the face opposite to the display face in at least part of the second display region, the part including a boundary portion between adjacent pixels within the second display region.

6. The display device according to claim 4, wherein a ratio of an area of the second film to an area of a light emitting region within the second display region is 30% or more.

7. The display device according to claim 4, wherein the second film has a function of cutting infrared light.

8. The display device according to claim 4,
wherein the second film is disposed at an opening formed by removal of part of the first film, and
a transmittance of a boundary portion between the first film and the second film varies continuously or stepwise from the first film to the second film.

9. The display device according to claim 4,
wherein the first film contains polyimide, and
the second film contains a material higher in transmittance than the polyimide of the first film.

10. The display device according to claim 4, wherein the second film has at least one of a concave portion or a convex portion.

11. The display device according to claim 10, further comprising: an optical lens including the second film.

12. The display device according to claim 10, further comprising: a moth-eye structure layer including the second film.

13. The display device according to claim 3,
wherein the first film is provided in at least part of the second display region, the at least part excluding a boundary portion between adjacent pixels within the second display region, and
an opening of the first film is provided at the boundary portion between the adjacent pixels within the second display region.

14. The display device according to claim 1,
wherein the first transmittance to visible light having a wavelength of 400 nm is 0 to 50%, and
the second transmittance to the visible light is 51 to 100%.

15. An electronic apparatus comprising:
a display device; and
a sensing device disposed opposite a display face of the display device,
wherein the display device includes:
a substrate;
a first display region disposed on the substrate, the first display region having a plurality of pixels; and
a second display region disposed on the substrate, the second display region having a plurality of pixels,
the substrate has a first transmittance in the first display region, and
the substrate has a second transmittance in the second display region higher than the first transmittance.

16. The electronic apparatus according to claim 15, wherein the sensing device includes an imaging sensor.

17. The electronic apparatus according to claim 15, wherein the sensing device includes a biometric-information detection sensor.

18. The electronic apparatus according to claim 15,
wherein a plurality of the second display regions is provided on the display face, and
a plurality of the sensing devices is disposed corresponding to the plurality of the second display regions.

19. The electronic apparatus according to claim 18, wherein the respective second transmittances of at least two of the plurality of the second display regions are different from each other.

20. A method for manufacturing a display device, the method comprising:
forming a first film having a first transmittance on a first support substrate;
forming a light emitting layer on the first film;
forming a protective film on the light emitting layer;
forming a second support substrate on the protective film;
removing the first support substrate; and
forming an opening at the first film in accordance with a disposition place of a sensing device.

21. The method according to claim 20, further comprising: forming a second film at the opening, the second film having a second transmittance higher than the first transmittance.

22. A method for manufacturing a display device, the method comprising:
forming a first film having a first transmittance on a support substrate;
forming an opening at the first film so as to be coincident with a disposition place of a sensing device;
filling the opening with an insulating member;
forming a first protective film on the first film;
forming a light emitting layer on the first protective film;
forming a second protective film on the light emitting layer; and
removing the insulating member to form the opening at the first film.

23. The method according to claim 22, further comprising: forming a second film at the opening formed by the removing, the second film being higher in transmittance than the first film.
